(19) United States
(12) Patent Application Publication
(10) Pub. No.: US 2025/0365901 A1
(43) Pub. Date: Nov. 27, 2025

(54) SYSTEM AND METHOD FOR CONTROLLING A COOLANT DISTRIBUTION UNIT

(71) Applicant: Stellar Energy Americas, Inc., Jacksonville, FL (US)

(72) Inventor: Brett Mason Griffin, Mount Pleasant, SC (US)

(21) Appl. No.: 19/214,745

(22) Filed: May 21, 2025

Related U.S. Application Data
(60) Provisional application No. 63/650,882, filed on May 22, 2024.

(51) Int. Cl. H05K 7/20

(52) U.S. Cl. CPC H05K 7/20836; H05K 7/20272; H05K 7/20763

(57) ABSTRACT

A system having at least one processor and a non-transitory computer-readable storage medium having instructions stored. The instructions, when executed by the at least one processor, cause the at least one processor to perform operations comprising receiving a temperature of a cooling fluid in a cooling fluid loop of a coolant distribution unit, comparing the temperature to a predetermined temperature, resulting in a comparison, and modulating a valve based on the comparison to adjust a flow of a supply fluid in a supply fluid loop of the coolant distribution unit, wherein modulating the valve increases or decreases the temperature of the cooling fluid. A method controls the valve.

### CROSS-REFERENCE TO RELATED APPLICATIONS

The present patent application claims priority benefit to U.S. Provisional Patent Application No. 63/650,882, filed May 22, 2024, the entire content of which is incorporated herein by reference.

### TECHNICAL FIELD

The present disclosure relates generally to a controller for a coolant distribution unit and a method for controlling the coolant distribution unit.

### BACKGROUND

Coolant distribution units are employed in cooling systems to distribute coolant, such as water or other fluids, to different parts of a machine or process that require cooling or temperature regulation. Coolant distribution units are employed, for example, in server rooms and data centers.

### BRIEF DESCRIPTION OF THE DRAWINGS

Features and advantages will be apparent from the following, more particular, description of various exemplary embodiments, as illustrated in the accompanying drawings, wherein like reference numbers generally indicate identical, functionally similar, and/or structurally similar elements.

FIG. 1 illustrates a schematic of a coolant distribution unit having a controller, according to the present disclosure.

FIG. 2 illustrates a method of operating a coolant distribution unit, according to the present disclosure.

FIG. 3 illustrates a method of controlling a coolant distribution unit, according to the present disclosure.

### DETAILED DESCRIPTION

Features, advantages, and embodiments of the present disclosure are set forth or apparent from a consideration of the following detailed description, drawings, and claims. Moreover, the following detailed description is exemplary and intended to provide further explanation without limiting the scope of the disclosure as claimed.

Various embodiments of the present disclosure are discussed in detail below. While specific embodiments are discussed, this is done for illustration purposes only. A person skilled in the relevant art will recognize that other components and configurations may be used without departing from the present disclosure.

As used herein, the terms “first” and “second,” and the like, may be used interchangeably to distinguish one component from another and are not intended to signify location or importance of the individual components.

The terms “upstream” and “downstream” refer to the relative direction with respect to fluid flow in a fluid pathway. For example, “upstream” refers to the direction from which the fluid flows (e.g., a location nearer to the fluid source), and “downstream” refers to the direction to which the fluid flows (e.g., a location farther from the fluid source).

The terms “coupled,” “fixed,” “attached,” “connected,” and the like, refer to both direct coupling, fixing, attaching, or connecting, as well as indirect coupling, fixing, attaching, or connecting through one or more intermediate components or features, unless otherwise specified herein. The terms include integral and unitary configurations.

The singular forms “a,” “an,” and “the” include plural references unless the context clearly dictates otherwise.

Here and throughout the specification and claims, range limitations are combined, and interchanged. Such ranges are identified and include all the sub-ranges contained therein unless context or language indicates otherwise. For example, all ranges disclosed herein are inclusive of the endpoints, and the endpoints are independently combinable with each other.

Data rooms and server rooms comprise a multitude of components that require cooling to ensure proper function and avoid overheating. These components include, for example, computer chips, microchips, servers, etc. Data rooms that house a large number of components or generate a large amount of data (e.g., artificial intelligence, blockchain mining, etc.) require a high rate of cooling. The present disclosure provides for a coolant distribution unit (“CDU”) for cooling the data rooms and also provides for a method of controlling the CDU and the components thereof to ensure proper cooling of the data room. The CDU flows cool water over the components (e.g., over the computer chips) to remove heat generated in the components and dispose of the heat outside of the data room.

The controller of the present disclosure provides for control of a CDU, and, thus, control of the cooling of the components of the data rooms and server rooms. The controller of the present disclosure provides valve control to regulate the flow of the cooling flow through the CDU, for initiating and stopping a pump of the CDU, for leak detection, for heat measurement (e.g., BTU measurement), for pressure and temperature feedback, or for any combination thereof. The present disclosure provides a system and method of controlling the flow of cooling fluid through a data room to cool the data room and for allowing the transfer of heat from the data room to outside of the building.

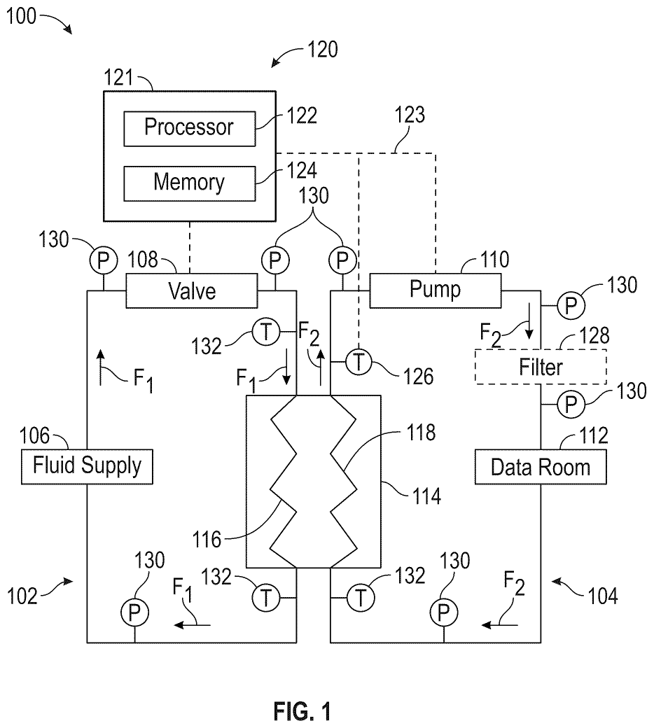

FIG. 1 illustrates a schematic of a CDU 100 according to the present disclosure. The CDU includes a first fluid loop 102 and a second fluid loop 104. The first fluid loop 102 includes a fluid supply 106 and a valve 108. The first fluid loop 102 is a recirculation loop. That is, a fluid provided from the fluid supply 106 is supplied along the first fluid loop 102 from the fluid supply 106 to the valve 108, through a heat exchanger, and back to the fluid supply 106. In some examples, the first fluid loop 102 is a closed loop. Although not illustrated in FIG. 1, the fluid supply 106 may be coupled to a cooling device, such as, for example, a dry cooler, an air cooled chiller, a water cooled chiller, etc., for providing a cool or chilled fluid supply 106 to be provided along the first fluid loop 102. The first fluid loop 102 is also referred to herein as a supply fluid loop 102.

The second fluid loop 104 includes a pump 110 and a component 112 to be cooled, such as, for example, a data room 112. For ease of reference, the component is referred to herein as the data room 112, however, other components are contemplated. The second fluid loop 104 may be a closed loop such that a fluid supplied along the second fluid loop 104 is pumped via the pump 110 through the data room 112 through the heat exchanger 114 and back to the pump 110. The second fluid loop 104 optionally includes one or more filters 128 provided upstream of the data room 112 such that the fluid flowing through the second fluid loop 104 is filtered with the filter 128 prior to flowing to the data room 112. The second fluid loop 104 is also referred to herein as a cooling fluid loop 104.

The CDU 100 includes the heat exchanger 114 through which the first fluid loop 102 and the second fluid loop 104 flow. The first fluid loop 102 flows through a first flow path 116 of the heat exchanger 114 and the second fluid loop 104 flows through a second flow path 118 of the heat exchanger 114. The first flow path 116 and the second flow path 118 are separate such that there is no mixing or direct contact between the fluid in the first fluid loop 102 and the fluid in the second fluid loop 104. The heat exchanger 114 allows for transfer of heat from inside a building (e.g., the second fluid loop 104) to outside of the building (e.g., the first fluid loop 102). That is, after the fluid in the second fluid loop 104 has cooled the data room 112, the heat picked up in the fluid from the data room is then transferred to the fluid in the first fluid loop 102. This allows for rejection of heat from the data room 112, while also cooling the fluid in the second fluid loop 104 to allow for the now cooled fluid in the second fluid loop 104 to be recirculated through the data room 112 to once again cool the data room 112.

The CDU 100 includes a control system 120 having a controller 121, one or more communication lines 123, and one or more sensors (e.g., sensor(s) 130, sensor(s) 132, sensor(s) 126, to be described in more detail to follow). The control system 120 has a controller 121 having a processor 122 and a memory 124. The controller 121 is communicatively coupled to the valve 108, the pump 110, and a temperature sensor 126 with the one or more communication lines 123. The one or more communication lines 123 enable the control system 120 to transmit and/or receive data, information, or other signals between the controller 121 and the valve 108, the pump 110, the temperature sensor 126, and other components of the CDU 100. Anytime there is operation in the data room 112, the pump 110 must be actuated to allow cooling fluid to flow therethrough. The control system 120 initiates the pump 110 operation. The valve 108 is selectively modulated by the control system 120 to adjust the cooling of the data room 112 by changing the cooling flow provided to the data room 112 by way of the heat exchanger 114, as is discussed in more detail to follow.

A single valve 108, pump 110, temperature sensor 126, filter 128, data room 112, and fluid source 106 are illustrated, but more may be provided. In instances where more are provided, the controller 121 may be communicatively coupled to the additional components with the one or more communication lines 123. For example, one or more pressure sensors 130 and one or more additional temperature sensors 132 may be included in the CDU 100. Although not illustrated for clarity, each of the sensors 130 and the sensors 132 are communicatively coupled to the controller 121 with the one or more communication lines 123. Other sensors located along the flow paths of the CDU 100 that are communicatively coupled to the controller 121 are also contemplated. The sensors may provide feedback on a particular component within the CDU 100 to the controller 121. The control system 120 may be configured to take action based on the feedback and/or may be configured to alert personnel or display the feedback.

The placement of the pressure sensors 130 and/or the temperature sensors 132 may be such as to allow differential or delta values to be monitored. For example, a temperature sensor 132 may be located at the inlet to the first flow path 116 and at the outlet of the first flow path 116. This allows for a change in temperature across the heat exchanger 114 of the first flow F1 to be monitored. With the delta temperature across the first flow path 116, the BTUs of the system may be determined (e.g., by the control system 120). In another example, a pressure sensor 130 may be located the inlet and the outlet of the pump 110 and/or at the inlet and the outlet of the valve 108. This allows for a change in pressure across the pump 110 to be monitored. This allows personnel to monitor, for example, malfunctions, clogs, etc., in the pump or within any conduit (e.g., the conduits allowing fluid flow through the first fluid loop 102 and the second fluid loop 104) that may then be remedied. The pressure sensors 130 and the temperature sensors 132 are optional and may be included in other locations not illustrated in FIG. 1.

As noted, the CDU 100 includes components that are communicatively and operatively coupled to the controller 121. The controller 121 is illustrated in FIG. 1 as being communicatively coupled with various components via the one or more communication lines 123, however, the controller 121 is not limited to being coupled to these components and may be connected to other illustrated or unillustrated components of the CDU 100, the facility, or the data room 112.

The control system 120 is configured to operate various aspects of the CDU 100. In this embodiment, the controller 121 of the control system 120 is a computing device having one or more processors 122 and one or more memories 124. The processor 122 may be any suitable processing device, including, but not limited to, a microprocessor, a microcontroller, an integrated circuit, a logic device, a programmable logic controller (PLC), an application-specific integrated circuit (ASIC), and/or a Field Programmable Gate Array (FPGA). The memory 124 may include one or more computer-readable media, including, but not limited to, non-transitory computer-readable media, a computer-readable non-volatile medium (e.g., a flash memory), a RAM, a ROM, hard drives, flash drives, and/or other memory devices.

The memory 124 may store information accessible by the processor 122, including computer-readable instructions that may be executed by the processor 122. The instructions may be any set of instructions or a sequence of instructions that, when executed by the processor 122, causes the processor 122 and the controller 121 to perform operations. In some embodiments, the instructions may be executed by the processor 122 to cause the processor 122 to complete any of the operations and functions for which the controller 121 is configured, as will be described further below. The instructions may be software written in any suitable programming language, or may be implemented in hardware. Additionally, and/or alternatively, the instructions may be executed in logically and/or virtually separate threads on the processor 122. The memory 124 may further store data that may be accessed by the processor 122.

The technology discussed herein makes reference to computer-based systems and actions taken by, and information sent to and from, computer-based systems. One of ordinary skill in the art will recognize that the inherent flexibility of computer-based systems allows for a great variety of possible configurations, combinations, and divisions of tasks and functionality between components and among components. For instance, processes discussed herein may be implemented using a single computing device or multiple computing devices working in combination. Databases, memory, instructions, and applications may be implemented on a single system or distributed across multiple systems. Distributed components may operate sequentially or in parallel.

Although not illustrated, the control system 120 may include a display communicatively coupled to the controller 121 to allow for personnel to monitor the CDU 100. The one or more communication lines 123 and/or any other communication lines in the CDU 100 may be wired or wireless.

During operation of the CDU 100, a fluid flow F1 flowing through the first fluid loop 102 is employed to cool a fluid flow F2 flowing through the second fluid loop 104, and, in turn, the now cooled fluid flow F2 is employed to cool the components in the data room 112. The fluid in both the fluid loops 102, 104 is recirculated such that there may be continuous cooling of the data room 112. The cooling needs of the data room 112 may define the temperature and/or the flow rate of one or both of the fluid flows F1 and F2.

The fluid flow F1 is provided from the fluid supply 106. The fluid supply 106 may be a water supply such that the fluid flow F1 is water, although other fluids are contemplated. In some examples, the fluid supply 106 is a cooling plant, a building water supply, or facility water supply, or a combination thereof. That is, the water is sourced from the available water to the building or facility in which the data room 112 is located. The fluid within the fluid supply 106 is a cooling fluid employed to lower the temperature of the fluid flowing in the second fluid loop 104, as described in more detail to follow. In some examples, the fluid supply 106 maintains the cooling fluid flowing through the fluid flow F1 at a predetermined temperature that is below the temperature of the fluid flowing through the second fluid loop 104.

The fluid flow F1 flows from the fluid supply 106 through the valve 108. As will be discussed in more detail to follow, the valve 108 may be modulated (e.g., by the controller 121) to control the flow of the fluid flow F1 through the first flow path 116 of the heat exchanger 114 and, thus, control a temperature of the fluid flowing through the second fluid loop 104. After passing through the valve 108, the fluid flow F1 passes through the first flow path 116 of the heat exchanger 114. In the second fluid loop 104, the fluid flow F2 flows in an opposing direction through the second flow path 118. In this manner, the fluid flow F2 is cooled with the cooling fluid that is flowing through the first flow path 116. The now cooled fluid flow F2 is pumped, via the pump 110, through the data room 112 to control the components therein. By cooling the components, the temperature of the fluid flow F2 is raised (as heat is rejected from the components in the data room 112 to the fluid flow F2). The higher temperature fluid flow F2 enters the heat exchanger 114 to be cooled by the cooling fluid flow F1.

The temperature sensor 126 is coupled to the second fluid loop 104 downstream of the heat exchanger 114. In some examples, the temperature sensor 126 is positioned at an outlet of the heat exchanger 114. The temperature sensor 126 thus monitors the temperature of the cooling fluid provided as the second flow F2 to cool the components of the data room 112. As discussed in more detail to follow, the temperature at the temperature sensor 126 is compared to the predetermined temperature to determine whether the CDU 100 is operating within the appropriate range to properly cool the data room 112.

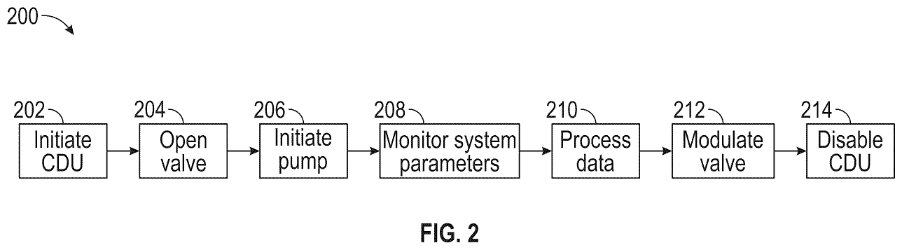

FIG. 2 illustrates a method 200 of controlling the above described operation of CDU 100 with the control system 120. In a first step 202, the CDU 100 is initiated. This may involve actuating (e.g., with the controller 121) the valve 108 to permit the fluid flow F1 therethrough (e.g., step 204, opening the valve 108). Once the valve 108 is open, the cooling fluid flow F1 is circulating through the first fluid loop 102. At step 206, the controller 121 initiates the pump 110. The pump 110, therefore, causes the fluid flow F2 to flow through the data room 112 to cool the components within the data room 112.

During operation of the CDU 100, the control system 120 monitors the system parameters (e.g., step 208). This monitoring may include monitoring, for example, flow rates, pressures, temperatures, or any combination thereof along any location of the first fluid loop 102 or the second fluid loop 104, or both fluid loops. Accordingly, sensors may be provided to monitor the respective parameters, such as, for example, temperature sensors, pressure sensors, flow rate sensors. The controller 121 processes the data, at step 210, with the processor 122. The processing may include comparing the data to predetermined values to ensure proper operation of the CDU 100. Based on the processed data, the valve 108 is modulated at step 212 with the controller 121. The modulation may be opening of the valve to increase flow therethrough, closing the valve to reduce flow therethrough, or taking no action with the valve. Opening the valve may include partial or full opening of the valve and closing the valve may include partial or full closing of the valve. In this manner, the valve 108 may be controlled such that a flow path through the valve is variably opened and closed. The steps 208, 210, and 212 may be continuously repeated throughout operation of the CDU 100. In this manner, the valve 108 may be continuously modulated during cooling of the data room 112. When the data room 112 is no longer in use, or cooling is no longer required, the CDU 100 is disabled or shut down at step 214.

One parameter that is monitored at step 208 and processed at step 210 is the temperature of the fluid flow F2 at the temperature sensor 126. Monitoring of the temperature at temperature sensor 126 allows for control the valve 108 with the controller 121. For example, a predetermined set temperature value or range may be stored in the memory 124 of the controller 121. The controller 121 may compare the measured temperature at the temperature sensor 126 to the predetermined set temperature value or range.

If the monitored temperature at the temperature sensor 126 is greater than the predetermined set temperature value or range, this may indicate the temperature of the flow F2 is not sufficient (e.g., not cool enough) for cooling of the data room 112 and may indicate that the temperature of the flow F2 needs to be lowered. The control system 120 opens the valve 108 to increase the flow of the cooling flow F1 through the heat exchanger 114. By increasing the flow F1, the cooling of the flow F2 within the heat exchanger is increased, thus reducing the temperature at the temperature sensor 126.

If the monitored temperature at the temperature sensor 126 is lesser than the predetermined set temperature value or range, this may indicate the temperature of the flow F2 is not sufficient (e.g., too cool) for cooling of the data room 112 and may indicate that the temperature of the flow F2 needs to be raised. The control system 120 closes the valve 108 to decrease the flow of the cooling flow F1 through the heat exchanger 114. By decreasing the flow F1, the cooling of the flow F2 within the heat exchanger is decreased, thus increasing the temperature at the temperature sensor 126.

As noted previously, the valve 108 is configured to open and close to varying degrees and adjustments to allow for adjustments of the flow therethrough. Furthermore, since the method 200 may continuously monitor the temperature, the valve 108 may be continuously modulated to maintain the temperature of the flow F2 within the predetermined set temperature value or range. The predetermined set temperature may be unique to a particular data room 112, a particular cooling fluid through the first or second fluid loops, a particular usage of the data room, or other factors. One factor that may define the predetermined set temperature may be, for example, the type of hardware in the data room (e.g., the type of microchip) and other factors that affect the heat generation in the data room and/or have required temperatures (such as microchips which may have manufacturer provided temperatures to be maintained for proper operation of the microchip).

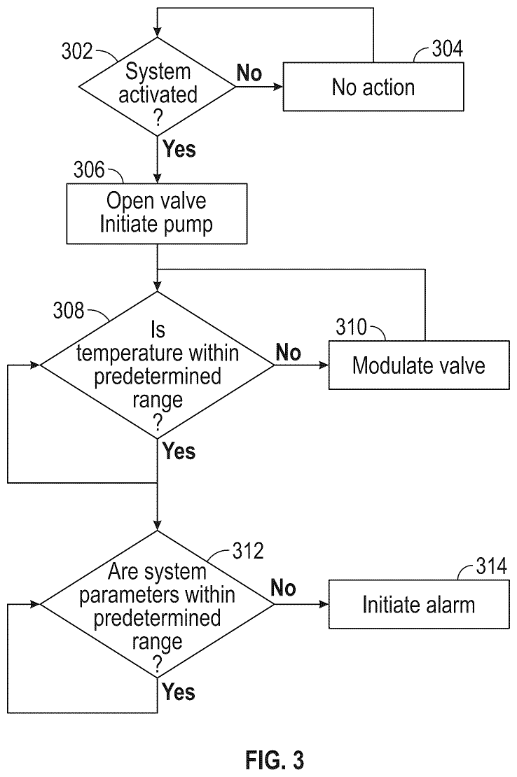

FIG. 3 illustrates an exemplary method 300 illustrating a logic path the controller 121 may employ to modulate the valve 108 during operation of the CDU 100. The method 300 may be employed in conjunction with the method 200.

At step 302, the controller 121 determines if the system (e.g., the CDU 100) is active. When the CDU 100 is not active, there is no fluid flowing in either the first fluid loop 102 or the second fluid loop 104. If the CDU 100 is not active (“No”), then the controller 121 takes no action at step 304 with respect to modulation of the valve 108. The controller 121 then continues to monitor for the status of the CDU 100. When the controller 121 determines that the CDU 100 is active (“Yes”), for example, by determining that one or more components of the data room 112 is activated and in need of cooling, etc., the controller 121 proceeds to step 306.

At step 306, the controller 121 opens the valve 108 to allow fluid flow through the first fluid loop 102 and, thus, to allow fluid flow through the heat exchanger 114. The controller 121 also initiates the pump 110 to allow fluid flow through the second fluid loop 104, and, thus, to allow fluid flow through the data room 112 and the heat exchanger 114. At this step, the fluid flow F1 is cooling the fluid flow F2 and, in turn, the cooled fluid flow F2 is cooling the components of the data room 112, as discussed previously.

As the fluid flows through the first fluid loop 102 and the second fluid loop 104, the controller 121 monitors various parameters of the CDU 100, and, in particular, the fluid flowing through the CDU, at step 308. As noted above, the parameter may be temperature, and, the controller 121 may determined at step 308 if the temperature is within the predetermined value or range to determine how to modulate the valve 108. If the temperature is not within the predetermined range (“No”), the valve is modulated open or closed at step 310, as discussed above, to bring the temperature of the fluid back into the predetermined. If the temperature is within the predetermined range (“Yes”), there is no change in the valve 108 position. In both cases, the controller 121 continues to monitor the temperature during operation of the CDU 100 to identify situations when modulation of the valve 108 is required.

During operation of the CDU 100, the controller 121 may also monitor other system parameters to determine if the system parameters are within a predetermined value or range at step 312. For example, the controller 121 may monitor if fluid is flowing through the CDU 100 while the data room 112 is active. In such a case, the components of the data room 112 may overheat if not properly cooled. If such an event is detected, the controller 121 may initiate an alarm at step 314 to alert personnel to remedy the situation. Other parameters or faults may be monitored at step 312 to initiate the alarm at step 314.

The controller 121 may operate the method 300 for the duration of the operation of the CDU 100. If, at any point in the method 300, the controller 121. Determines the data room 112 is no longer in need of cooling (e.g., the data room 112 is not in use), the controller 121 may close the valve 108 and cease function of the pump 110. In this manner, the CDU 100 is controlled to operate only when cooling of the data room 112 is required.

Accordingly, the system and the method of the present disclosure maintain the temperature of the cooling flow through the data room at a predetermined temperature value or within a predetermined temperature range. Such control is important in data rooms to ensure proper cooling of the hardware within the data room, which affects the function of the data room as a whole. If the data room is not cooled properly, the hardware may overheat causing malfunctions within the data room.

In other words, the control system of the present disclosure provides one or more of the following advantages (1) the control system may be applied to water-to-water CDU application, (2) the control system has the ability to start and stop the flow through the cooling loop (e.g., start and stop the pump), (3) the control system provides VFD control, (4) the control system may include additional pressure transmitters or temperature transmitters, (5) the control system may provide leak detection), (6) the control system provides BTU monitoring on both the supply fluid loop and the cooling fluid loop, (7) the control system provides flow indication/monitoring on both the supply fluid loop and the cooling fluid loop, (8) the control system provides cold side BTUs and flow measurement based on valve position (e.g., from rotation sensor feedback and DeltaP valve calibration to that specific valve position), and/or (9) the control system provides hot side (data center side) flow indication achieved through calculations using cold side BTUs and hot side temperature differentials

Further aspects are provided by the subject matter of the following clauses.

A system comprising at least one processor; and a non-transitory computer-readable storage medium having instructions stored which, when executed by the at least one processor, cause the at least one processor to perform operations comprising: receiving a temperature of a cooling fluid in a cooling fluid loop of a coolant distribution unit; comparing the temperature to a predetermined temperature, resulting in a comparison; and modulating a valve based on the comparison to adjust a flow of a supply fluid in a supply fluid loop of the coolant distribution unit, wherein modulating the valve increases or decreases the temperature of the cooling fluid.

The system of the preceding clause, the non-transitory computer-readable storage medium having additional instructions store which, when executed by the at least one processor, cause the at least one processor to perform operations comprising: opening the valve to increase a flow rate of the supply fluid and decrease the temperature of the cooling fluid, wherein opening the valve includes incremental opening of the valve.

The system of any preceding clause, the non-transitory computer-readable storage medium having additional instructions store which, when executed by the at least one processor, cause the at least one processor to perform operations comprising: closing the valve to decrease a flow rate of the supply fluid and increase the temperature of the cooling fluid, wherein closing the valve includes incremental closing of the valve.

The system of any preceding clause, wherein the temperature of the cooling fluid is received at an outlet of a heat exchanger that permits heat transfer communication between the cooling fluid loop and the supply fluid loop.

The system of the preceding clause, the non-transitory computer-readable storage medium having additional instructions store which, when executed by the at least one processor, cause the at least one processor to perform operations comprising: monitoring a second temperature of the cooling fluid at an inlet of the heat exchanger; and calculating a delta temperature of the temperature and the second temperature to determine BTUs generated.

The system of any preceding clause, the non-transitory computer-readable storage medium having additional instructions store which, when executed by the at least one processor, cause the at least one processor to perform operations comprising: receiving a pressure of the cooling fluid in the cooling fluid loop.

The system of any preceding clause, the non-transitory computer-readable storage medium having additional instructions store which, when executed by the at least one processor, cause the at least one processor to perform operations comprising: receiving a pressure of the supply fluid in the supply fluid loop.

The system of any preceding clause, the non-transitory computer-readable storage medium having additional instructions store which, when executed by the at least one processor, cause the at least one processor to perform operations comprising: receiving a supply fluid temperature of the supply fluid in the supply fluid loop; and modulating the valve based on the supply fluid temperature.

The system of any preceding clause, the non-transitory computer-readable storage medium having additional instructions store which, when executed by the at least one processor, cause the at least one processor to perform operations comprising: calculating a flow rate of the cooling fluid through the cooling fluid loop and a flow rate of the supply fluid through the supply fluid loop; comparing the flow rate of the cooling fluid to a predetermined cooling fluid flow rate and comparing the flow rate of the supply fluid to a predetermined supply fluid flow rate to generate a comparison; and determining if there is a leak in the cooling fluid loop, the supply fluid loop, or both, based on the comparison.

A method for controlling a coolant distribution unit, the method comprising: receiving, at a controller, a temperature of a cooling fluid in a cooling fluid loop of a coolant distribution unit; comparing, with at least one processor of the controller, the temperature to a predetermined temperature, resulting in a comparison; and modulating, with the at least one processor, a valve based on the comparison to adjust a flow of a supply fluid in a supply fluid loop of the coolant distribution unit, wherein modulating the valve increases or decreases the temperature of the cooling fluid.

The method of the preceding clause, further comprising: opening, with the at least one processor, the valve to increase a flow rate of the supply fluid and decrease the temperature of the cooling fluid, wherein opening the valve includes incremental opening of the valve.

The method of any preceding clause, further comprising: closing, with the at least one processor, the valve to decrease a flow rate of the supply fluid and increase the temperature of the cooling fluid, wherein closing the valve includes incremental closing of the valve.

The method of any preceding clause, wherein the temperature of the cooling fluid is received at an outlet of a heat exchanger that permits heat transfer communication between the cooling fluid loop and the supply fluid loop.

The method of the preceding clause, further comprising: monitoring a second temperature of the cooling fluid at an inlet of the heat exchanger; and calculating a delta temperature of the temperature and the second temperature to determine BTUs generated.

The method of any preceding clause, further comprising monitoring, with the controller, a pressure of the cooling fluid in the cooling fluid loop or a pressure of the supply fluid in the supply fluid loop.

The method of any preceding clause, further comprising initiating, with the controller, a flow of the supply fluid prior to initiating a flow of the cooling fluid.

The method of any preceding clause, further comprising opening, with the controller, the valve prior to initiating a pump that flows the cooling fluid.

The method of any preceding clause, further comprising continuously receiving, at the controller, the temperature of the cooling fluid, continuously comparing the temperature, and continuously modulating the valve.

The method of any preceding clause, further comprising monitoring, with the controller, system parameters of the coolant distribution unit to detect faults within one or more components of the coolant distribution unit.

The method of the preceding clause, further comprising initiating an alarm, with the processor, if a fault is detected.

The method of any preceding clause, further comprising: calculating, with the processor, a flow rate of the cooling fluid through the cooling fluid loop and a flow rate of the supply fluid through the supply fluid loop; comparing, with the processor, the flow rate of the cooling fluid to a predetermined cooling fluid flow rate and comparing the flow rate of the supply fluid to a predetermined supply fluid flow rate to generate a comparison; and determining, with the processor, if there is a leak in the cooling fluid loop, the supply fluid loop, or both, based on the comparison.

Although the foregoing description is directed to the preferred embodiments of the present disclosure, other variations and modifications will be apparent to those skilled in the art and may be made without departing from the spirit or the scope of the disclosure. Moreover, features described in connection with one embodiment of the present disclosure may be used in conjunction with other embodiments, even if not explicitly stated above.

1. A system comprising:
at least one processor; and
a non-transitory computer-readable storage medium having instructions stored which, when executed by the at least one processor, cause the at least one processor to perform operations comprising:
receiving a temperature of a cooling fluid in a cooling fluid loop of a coolant distribution unit;
comparing the temperature to a predetermined temperature, resulting in a comparison; and
modulating a valve based on the comparison to adjust a flow of a supply fluid in a supply fluid loop of the coolant distribution unit, wherein modulating the valve increases or decreases the temperature of the cooling fluid.

2. The system of claim 1, the non-transitory computer-readable storage medium having additional instructions store which, when executed by the at least one processor, cause the at least one processor to perform operations comprising:
opening the valve to increase a flow rate of the supply fluid and decrease the temperature of the cooling fluid, wherein opening the valve includes incremental opening of the valve.

3. The system of claim 1, the non-transitory computer-readable storage medium having additional instructions store which, when executed by the at least one processor, cause the at least one processor to perform operations comprising:
closing the valve to decrease a flow rate of the supply fluid and increase the temperature of the cooling fluid, wherein closing the valve includes incremental closing of the valve.

4. The system of claim 1, wherein the temperature of the cooling fluid is received at an outlet of a heat exchanger that permits heat transfer communication between the cooling fluid loop and the supply fluid loop.

5. The system of claim 4, the non-transitory computer-readable storage medium having additional instructions store which, when executed by the at least one processor, cause the at least one processor to perform operations comprising:
monitoring a second temperature of the cooling fluid at an inlet of the heat exchanger; and
calculating a delta temperature of the temperature and the second temperature to determine BTUs generated.

6. The system of claim 1, the non-transitory computer-readable storage medium having additional instructions store which, when executed by the at least one processor, cause the at least one processor to perform operations comprising:
receiving a pressure of the cooling fluid in the cooling fluid loop.

7. The system of claim 1, the non-transitory computer-readable storage medium having additional instructions store which, when executed by the at least one processor, cause the at least one processor to perform operations comprising:
receiving a pressure of the supply fluid in the supply fluid loop.

8. The system of claim 1, the non-transitory computer-readable storage medium having additional instructions store which, when executed by the at least one processor, cause the at least one processor to perform operations comprising:
receiving a supply fluid temperature of the supply fluid in the supply fluid loop; and
modulating the valve based on the supply fluid temperature.

9. The system of claim 1, the non-transitory computer-readable storage medium having additional instructions store which, when executed by the at least one processor, cause the at least one processor to perform operations comprising:
calculating a flow rate of the cooling fluid through the cooling fluid loop and a flow rate of the supply fluid through the supply fluid loop;
comparing the flow rate of the cooling fluid to a predetermined cooling fluid flow rate and comparing the flow rate of the supply fluid to a predetermined supply fluid flow rate to generate a comparison; and
determining if there is a leak in the cooling fluid loop, the supply fluid loop, or both, based on the comparison.

10. A method for controlling a coolant distribution unit, the method comprising:
receiving, at a controller, a temperature of a cooling fluid in a cooling fluid loop of a coolant distribution unit;
comparing, with at least one processor of the controller, the temperature to a predetermined temperature, resulting in a comparison; and
modulating, with the at least one processor, a valve based on the comparison to adjust a flow of a supply fluid in a supply fluid loop of the coolant distribution unit, wherein modulating the valve increases or decreases the temperature of the cooling fluid.

11. The method of claim 10, further comprising:
opening, with the at least one processor, the valve to increase a flow rate of the supply fluid and decrease the temperature of the cooling fluid, wherein opening the valve includes incremental opening of the valve.

12. The method of claim 10, further comprising:
closing, with the at least one processor, the valve to decrease a flow rate of the supply fluid and increase the temperature of the cooling fluid, wherein closing the valve includes incremental closing of the valve.

13. The method of claim 10, wherein the temperature of the cooling fluid is received at an outlet of a heat exchanger that permits heat transfer communication between the cooling fluid loop and the supply fluid loop.

14. The method of claim 13, further comprising:
monitoring a second temperature of the cooling fluid at an inlet of the heat exchanger; and
calculating a delta temperature of the temperature and the second temperature to determine BTUs generated.

15. The method of claim 10, further comprising monitoring, with the controller, a pressure of the cooling fluid in the cooling fluid loop or a pressure of the supply fluid in the supply fluid loop.

16. The method of claim 10, further comprising initiating, with the controller, a flow of the supply fluid prior to initiating a flow of the cooling fluid.

17. The method of claim 10, further comprising opening, with the controller, the valve prior to initiating a pump that flows the cooling fluid.

18. The method of claim 10, further comprising continuously receiving, at the controller, the temperature of the cooling fluid, continuously comparing the temperature, and continuously modulating the valve.

19. The method of claim 10, further comprising monitoring, with the controller, system parameters of the coolant distribution unit to detect faults within one or more components of the coolant distribution unit.

20. The method of claim 19, further comprising initiating an alarm, with the processor, if a fault is detected.

21. The method of claim 10, further comprising:
calculating, with the processor, a flow rate of the cooling fluid through the cooling fluid loop and a flow rate of the supply fluid through the supply fluid loop;
comparing, with the processor, the flow rate of the cooling fluid to a predetermined cooling fluid flow rate and comparing the flow rate of the supply fluid to a predetermined supply fluid flow rate to generate a comparison; and
determining, with the processor, if there is a leak in the cooling fluid loop, the supply fluid loop, or both, based on the comparison.
